(19) United States
(12) Patent Application Publication
(10) Pub. No.: US 2018/0030291 A1
(43) Pub. Date: Feb. 1, 2018

(54) COMPOSITIONS CONTAINING HOLE CARRIER COMPOUNDS AND POLYMERIC ACIDS, AND USES THEREOF

(71) Applicant: NISSAN CHEMICAL INDUSTRIES, LTD., Tokyo (JP)

(72) Inventors: Floryan DE CAMPO, Pittsburgh, PA (US); Mitchell SASALA, New Stanton, PA (US); Elena SHEINA, Pittsburgh, PA (US); Robert SWISHER, Pittsburgh, PA (US); Jing WANG, Gibsonia, PA (US)

(21) Appl. No.: 15/553,037

(22) PCT Filed: Feb. 29, 2016
(86) PCT No.: PCT/US2016/020087

§ 371 Date: Aug. 23, 2017

Related U.S. Application Data
(60) Provisional application No. 62/127,346, filed on Mar. 3, 2015.

(51) Int. Cl. C09D 11/102; C09D 11/52; C09D 11/106; H01L 51/00

(52) U.S. Cl. CPC C09D 11/102; H01L 51/0003; C09D 11/52; C09D 11/106; H01L 51/0036; H01L 51/004; H01L 51/0043; H01L 51/5088

(57) ABSTRACT

Described herein are ink compositions comprising hole carrier compounds typically conjugated polymers, polymeric acids, and organic solvent, and uses thereof, for example, in organic electronic devices. The polymeric acid comprises one or more repeating units comprising at least one alkyl or alkoxy group which is substituted by at least one fluorine atom and at least one sulfonic acid moiety.

### CROSS REFERENCE TO RELATED APPLICATIONS

This application claims the priority of U.S. Provisional Application No. 62/127,346 filed Mar. 3, 2015. The entire contents of this application is explicitly incorporated herein by this reference.

### FIELD OF THE INVENTION

The present disclosure relates to ink compositions comprising hole carrier compounds, typically conjugated polymers, and polymeric acids, and uses thereof, for example, in organic electronic devices.

### BACKGROUND

Although useful advances are being made in energy saving devices such as, for example, organic-based organic light emitting diodes (OLEDs), polymer light emitting diodes (PLEDs), phosphorescent organic light emitting diodes (PHOLEDs), and organic photovoltaic devices (OPVs), further improvements are still needed in providing better materials processing and/or device performance for commercialization. For example, one promising type of material used in organic electronics is the conducting polymers including, for example, polythiophenes. However, problems can arise with polymers' purity, processability, and instability in their neutral and/or conductive states. Also, it is important to have very good control over the solubility of polymers utilized in alternating layers of various devices' architectures (e.g., orthogonal or alternating solubility properties among adjacent layers in particular device architecture). These layers, for example, also known as hole injection layers (HILs) and hole transport layers (HTLs), can present difficult problems in view of competing demands and the need for very thin, but high quality, films.

There is an ongoing unresolved need for a good platform system to control properties of hole injection and transport layers, such as solubility, thermal/chemical stability, and electronic energy levels, such as HOMO and LUMO, so that the compounds can be adapted for different applications and to function with different compounds, such as light emitting layers, photoactive layers, and electrodes. Good solubility, intractability, and thermal stability properties are important. Also of importance is the ability to tune HIL resistivity and HIL layer thickness while retaining high transparency and low operating voltage. The ability to formulate the system for a particular application and provide the required balance of such properties is also important.

### SUMMARY OF THE INVENTION

In a first aspect, the present disclosure relates to a non-aqueous ink composition comprising:
(a) at least one hole carrier compound; and
(b) at least one polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group; and
(c) a liquid carrier comprising at least one organic solvent.

In a second aspect, the present disclosure relates to a process for forming a hole-carrying film, the process comprising:
1) coating a substrate with a non-aqueous ink composition disclosed herein; and
2) annealing the coating on the substrate, thereby forming the hole-carrying film.

In a third aspect, the present disclosure relates to a device comprising the films prepared according to the processes described herein, wherein the device is an OLED, OPV, transistor, capacitor, sensor, transducer, drug release device, electrochromic device, or battery device.

An objective of the present invention is to provide the ability to tune electrical properties, such as resistivity, of HILs in a device comprising the compositions described herein.

Another objective of the present invention is to provide the ability to tune film thickness and retain high transparency or low absorbance in the visible spectrum (transmittance >90% T) in a device comprising the compositions described herein.

### BRIEF DESCRIPTION OF THE FIGURES

FIG. 1 shows the UV-vis spectra of films made from inventive ink 1 of different % total solids content before and after annealing.

FIGS. 2A and 2B show the images of films formed on glass and films formed on ITO, respectively, under 500× magnification.

FIGS. 3A and 3B show the images of films formed on glass and films formed on ITO, respectively, under 1000× magnification.

FIG. 4 shows a plot of current density as a function of voltage for HILs made from inventive inks 1 and 2 annealed at 200 and 250° C.

FIG. 5 shows a plot of current density as a function of voltage for HILs made from inventive inks 3 and 4 annealed at 200 and 250° C.

### DETAILED DESCRIPTION

As used herein, the terms “a”, “an”, or “the” means “one or more” or “at least one” unless otherwise stated.

As used herein, the term “comprises” includes “consists essentially of” and “consists of.” The term “comprising” includes “consisting essentially of” and “consisting of.”

The phrase “free of” means that there is no external addition of the material modified by the phrase and that there is no detectable amount of the material that may be observed by analytical techniques known to the ordinarily-skilled artisan, such as, for example, gas or liquid chromatography, spectrophotometry, optical microscopy, and the like.

Throughout the present disclosure, various publications may be incorporated by reference. Should the meaning of any language in such publications incorporated by reference conflict with the meaning of the language of the present disclosure, the meaning of the language of the present disclosure shall take precedence, unless otherwise indicated.

As used herein, the terminology “(Cx-Cy)” in reference to an organic group, wherein x and y are each integers, means that the group may contain from x carbon atoms to y carbon atoms per group.

As used herein, the term “alkyl” means a monovalent straight or branched saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, 2-ethylhexyl, octyl, hexadecyl, octadecyl, eicosyl, behenyl, tricontyl, and tetracontyl.

As used herein, the term “fluoroalkyl” means an alkyl radical as defined herein, more typically a (C₁-C₄₀) alkyl radical, that is substituted with one or more fluorine atoms. Examples of fluoroalkyl groups include, for example, difluoromethyl, trifluoromethyl, perfluoroalkyl, 1H,1H,2H,2H-perfluorooctyl, perfluoroethyl, and —CH₂CF₃.

As used herein, the term “alkoxy” means a monovalent radical denoted as —O-alkyl, wherein the alkyl group is as defined herein. Examples of alkoxy groups, include, but are not limited to, methoxy, ethoxy, n-propoxy, isopropoxy, n-butoxy, isobutoxy, and tert-butoxy.

As used herein, alkyl groups and/or the alkyl portion of alkoxy groups may optionally be interrupted by one or more ether linkage (—O—) groups.

As used herein, the term “aryl” means a monovalent unsaturated hydrocarbon radical containing one or more six-membered carbon rings in which the unsaturation may be represented by three conjugated double bonds. Aryl radicals include monocyclic aryl and polycyclic aryl. Polycyclic aryl refers to a monovalent unsaturated hydrocarbon radical containing more than one six-membered carbon ring in which the unsaturation may be represented by three conjugated double bonds wherein adjacent rings may be linked to each other by one or more bonds or divalent bridging groups or may be fused together. Examples of aryl radicals include, but are not limited to, phenyl, anthracenyl, naphthyl, phenanthrenyl, fluorenyl, and pyrenyl.

Any substituent described herein may optionally be substituted at one or more carbon atoms with one or more, same or different, substituents described herein. For instance, an alkyl group may be further substituted with an aryl group or another alkyl group. Any substituent described herein may optionally be substituted at one or more carbon atoms with one or more substituents selected from the group consisting of halogen, such as, for example, F, Cl, Br, and I; nitro (NO₂), cyano (CN), and hydroxy (OH).

As used herein, the term “hole carrier compound” refers to any compound that is capable of facilitating the movement of holes, i.e., positive charge carriers, and/or blocking the movement of electrons, for example, in an electronic device. Hole carrier compounds include compounds useful in layers (HTLs), hole injection layers (HILs) and electron blocking layers (EBLs) of electronic devices, typically organic electronic devices, such as, for example, organic light emitting devices.

As used herein, the term “doped” in reference to a hole carrier compound, for example, a conjugated polymer, means that the hole carrier compound has undergone a chemical transformation, typically an oxidation or reduction reaction, more typically an oxidation reaction, facilitated by a dopant. As used herein, the term “dopant” refers to a substance that oxidizes or reduces, typically oxidizes, a hole carrier compound, for example, a conjugated polymer. Herein, the process wherein a hole carrier compound undergoes a chemical transformation, typically an oxidation or reduction reaction, more typically an oxidation reaction, facilitated by a dopant is called a “doping reaction” or simply “doping”. Doping alters the properties of the conjugated polymer, which properties may include, but may not be limited to, electrical properties, such as resistivity and work function, mechanical properties, and optical properties. In the course of a doping reaction, the hole carrier compound becomes charged, and the dopant, as a result of the doping reaction, becomes the oppositely-charged counterion for the doped hole carrier compound. As used herein, a substance must chemically react, oxidize or reduce, typically oxidize, a hole carrier compound to be referred to as a dopant. Substances that do not react with the hole carrier compound but may act as counterions are not considered dopants according to the present disclosure. Accordingly, the term “undoped” in reference to a hole carrier compound, for example a conjugated polymer, means that the hole carrier compound has not undergone a doping reaction as described herein.

The present disclosure relates to a non-aqueous ink composition comprising:
(a) at least one hole carrier compound; and
(b) at least one polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group; and
(c) a liquid carrier comprising at least one organic solvent.

Hole carrier compounds are known in the art and are commercially available. Hole carrier compounds may be, for example, low molecular weight compounds or high molecular weight compounds. Hole carrier compounds may be non-polymeric or polymeric. Non-polymeric hole carrier compounds include, but are not limited to, cross-linkable and non-crosslinked small molecules. Examples of non-polymeric hole carrier compounds include, but are not limited to, N,N′-bis(3-methylphenyl)-N,N′-bis(phenyl)benzidine (CAS #65181-78-4); N,N′-bis(4-methylphenyl)-N,N′-bis(phenyl)benzidine, N,N′-bis(2-naphtalenyI)—N—N′-bis(phenylbenzidine) (CAS #139255-17-1); 1,3,5-tris(3-methyldiphenylamino)benzene (also referred to as m-MTDAB); N,N′-bis(1-naphtalenyl)-N,N′-bis(phenyl)benzidine (CAS #123847-85-8, NPB); 4,4′,4″-tris(N,N-phenyl-3-methylphenylamino)triphenylamine (also referred to as m-MTDATA, CAS #124729-98-2); 4,4′,N,N′-diphenylcarbazole (also referred to as CBP, CAS #58328-31-7); 1,3,5-tris(diphenylamino)benzene, 1,3,5-tris(2-(9-ethylcarbazyl-3)ethylene)benzene, 1,3,5-tris[(3-methylphenyl)phenylamino]benzene, 1,3-bis(N-carbazolyl)benzene, 1,4-bis(diphenylamino)benzene; 4,4′-bis(N-carbazolyl)-1,1′-biphenyl, 4,4′-bis(N-carbazolyl)-1,1′-biphenyl, 4-(dibenzylamino)benzaldehyde-N,N-diphenylhydrazone, 4-(diethylamino)benzaldehyde diphenylhydrazone; 4-(dimethylamino)benzaldehyde diphenylhydrazone; 4-(diphenylamino)benzaldehyde diphenylhydrazone; 9-ethyl-3-carbazolecarboxaldehyde diphenylhydrazone; copper(II) phthalocyanine; N,N′-bis(3-methylphenyl)-N,N′-diphenylbenzidine, N,N′-di-[(1-naphthyl)-N,N′-diphenyl]-1,1′-biphenyl)-4,4′-diamine; N,N′-diphenyl-N,N′-di-p-tolylbenzene-1,4-diamine, tetra-N-phenylbenzidine; titanyl phthalocyanine; tri-p-tolylamine; tris(4-carbazol-9-ylphenyl)amine; and tris[4-(diethylamino)phenyl]amine.

In an embodiment, the at least one hole carrier compound is polymeric. Polymeric hole carrier compounds include, but are not limited to, polymers which comprise hole carrier moieties in the main-chain or side chain, and conjugated polymers, such as, for example, linear conjugated polymers or conjugated polymer brushes. As used herein, “conjugated polymer” refers to any polymer having a backbone comprising a continuous system of sp²-hybridized atoms over which π electrons can delocalize.

In an embodiment, the at least one hole carrier compound is a conjugated polymer. Conjugated polymers are known in the art, including their use in organic electronics devices. The conjugated polymers used according to the present disclosure may be homopolymers, copolymers, including statistical, random, gradient, and block copolymers. For a polymer comprising a monomer A and a monomer B, block copolymers include, for example, A-B diblock copolymers, A-B-A triblock copolymers, and -(AB)ₙ-multiblock copolymers. Synthetic methods, doping, and polymer characterization, including regioregular polythiophenes with side groups, is provided in, for example, U.S. Pat. No. 6,602,974 to McCullough et al. and U.S. Pat. No. 6,166,172 to McCullough et al., the entireties of which are hereby incorporated by reference.

Examples of conjugated polymers include, but are not limited to:

polythiophenes comprising repeating units, such as, for example,

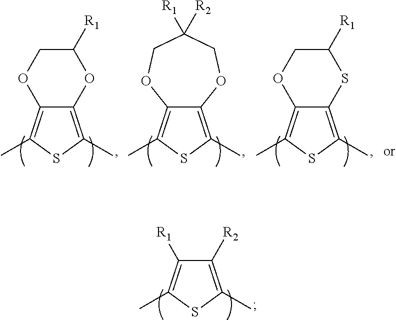

polythienothiophenes comprising repeating units, such as, for example,

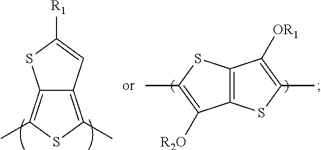

polyselenophenes comprising repeating units, such as, for example,

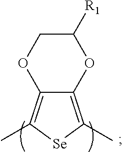

polypyrroles comprising repeating units, such as, for example,

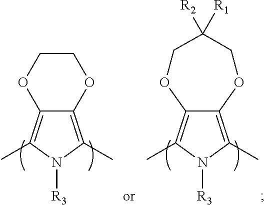

polyfurans, polytellurophenes, polyanilines, polyarylamines, and polyarylenes (e.g., polyphenylenes, polyphenylene vinylenes, and polyfluorenes. In the above structures, the groups R₁, R₂, and R₃ can be, independently of each other, optionally substituted C₁-C₂₅ groups, typically C₁-C₁₀ groups, more typically C₁-C₈ groups, including alkyl, fluoroalkyl, alkoxy, and polyether groups. The groups R₁ and/or R₂ may also be hydrogen (H). The groups can be electron-withdrawing or electron-releasing groups. The side groups can provide solubility. The structures described and illustrated herein can be incorporated into a polymer backbone or side chain.

Additional suitable polymeric hole carrier compounds include, but are not limited to, poly[(9,9-dihexylfluorenyl-2,7-diyl)-alt-co-(N,N′bis{p-butylphenyl}-1,4-diaminophenylene)]; poly[(9,9-dioctylfluorenyl-2,7-diyl)-alt-co-(N,N′-bis{p-butylphenyl}-1,1′-biphenylene-4,4′-diamine)]; poly(9,9-dioctylfluorene-co-N-(4-butylphenyl)diphenylamine) (also referred to as TFB) and poly[N,N′-bis(4-butylphenyl)-N,N′-bis(phenyl)-benzidine] (commonly referred to as poly-TPD).

In an embodiment, the conjugated polymer is a polythiophene.

In an embodiment, the polythiophene comprises a repeating unit complying with formula (I)

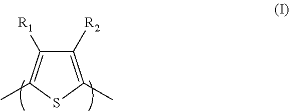

wherein R₁ and R₂ are each, independently, H, alkyl, fluoroalkyl, polyether, or alkoxy group.

In an embodiment, R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d}, are each, independently, H, alkyl, fluoroalkyl, or aryl; Rₑ is H, alkyl, fluoroalkyl, or aryl; p is 1, 2, or 3; and R_{f} is alkyl, fluoroalkyl, or aryl.

In an embodiment, R₁ is H and R₂ is other than H. In such an embodiment, the repeating unit is derived from a 3-substituted thiophene.

The polythiophene can be a regiorandom or a regioregular compound. Due to its asymmetrical structure, the polymerization of 3-substituted thiophenes produces a mixture of polythiophene structures containing three possible regiochemical linkages between repeat units. The three orientations available when two thiophene rings are joined are the 2,2′; 2,5′, and 5,5′ couplings. The 2,2′ (or head-to-head) coupling and the 5,5′ (or tail-to-tail) coupling are referred to as regiorandom couplings. In contrast, the 2,5′ (or head-to-tail) coupling is referred to as a regioregular coupling. The degree of regioregularity can be, for example, about 0 to 100%, or about 25 to 99.9%, or about 50 to 98%. Regioregularity may be determined by standard methods known to those of ordinary skill in the art, such as, for example, using NMR spectroscopy.

In an embodiment, the polythiophene is regioregular. In some embodiments, the regioregularity of the polythiophene can be at least about 85%, typically at least about 95%, more typically at least about 98%. In some embodiments, the degree of regioregularity can be at least about 70%, typically at least about 80%. In yet other embodiments, the regioregular polythiophene has a degree of regioregularity of at least about 90%, typically a degree of regioregularity of at least about 98%.

3-substituted thiophene monomers, including polymers derived from such monomers, are commercially-available or may be made by methods known to those of ordinary skill in the art. Synthetic methods, doping, and polymer characterization, including regioregular polythiophenes with side groups, is provided in, for example, U.S. Pat. No. 6,602,974 to McCullough et al. and U.S. Pat. No. 6,166,172 to McCullough et al.

In an embodiment, R₁ is H and R₂ is —O[C(RₐR_{b})—C(R_{c}R_{d})—O]ₚ-Rₑ, or —OR_{f}. In an embodiment, R₁ is H and R₂ is —O[C(RₐR_{b})—C(R_{c}R_{d})—O]ₚ—Rₑ.

In an embodiment, each occurrence of Rₐ, R_{b}, R_{c}, and R_{d}, are each, independently, H, (C₁-C₈)alkyl, (C₁-C₈)fluoroalkyl, or phenyl; and Rₑ and R_{f} are each, independently, H, (C₁-C₈)alkyl, (C₁-C₈)fluoroalkyl, or phenyl.

In an embodiment, R₂ is —O[CH₂—CH₂—O]ₚ—Rₑ. In an embodiment, R₂ is —OR_{f}.

In an embodiment, Rₑ is H, methyl, propyl, or butyl. In an embodiment, R_{f} is —CH₂CF₃.

In an embodiment, the polythiophene comprises a repeating unit

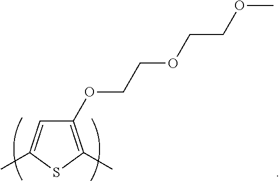

It would be understood by the ordinarily-skilled artisan that the repeating unit

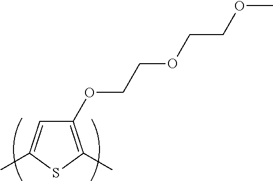

is derived from a monomer represented by the structure

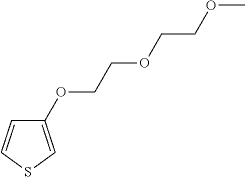

3-(2-(2-methoxyethoxy)ethoxy)thiophene [referred to herein as 3-MEET]

In another embodiment, R₁ and R₂ are both other than H. In such an embodiment, the repeating unit is derived from a 3,4-disubstituted thiophene.

In an embodiment, R₁ and R₂ are each, independently, —O[C(RₐR_{b})—C(R_{c}R_{d})—O]ₚ—Rₑ or —OR_{f}.

In an embodiment, R₁ and R₂ are both —O[C(RₐR_{b})—C(R_{c}R_{d})—O]ₚ—Rₑ. In an embodiment, R₁ and R₂ are both —OR_{f}. R₁ and R₂ may be the same or different.

In an embodiment, each occurrence of Rₐ, R_{b}, R_{c}, and R_{d}, are each, independently, H, (C₁-C₈)alkyl, (C₁-C₈)fluoroalkyl, or phenyl; and Rₑ and R_{f} are each, independently, H, (C₁-C₈)alkyl, (C₁-C₈)fluoroalkyl, or phenyl.

In an embodiment, R₁ and R₂ are each —O[CH₂—CH₂—O]ₚ—Rₑ. In an embodiment, R₁ and R₂ are each —O[CH(CH₃)—CH₂—O]ₚ—Rₑ.

In an embodiment, Rₑ is H, methyl, propyl, or butyl. In an embodiment, R_{f} is —CH₂CF₃.

In an embodiment, the polythiophene comprises a repeating unit

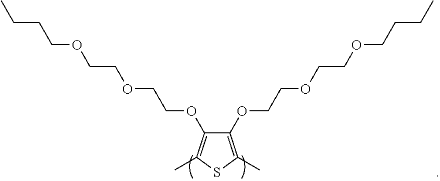

It would be understood by the ordinarily-skilled artisan that the repeating unit

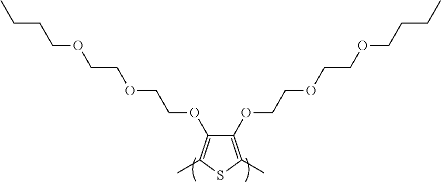

is derived from a monomer represented by the structure

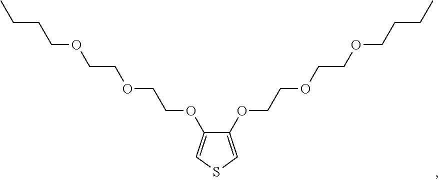 [SMILES: CCCCOCCOCCOc1cscc1OCCOCCOCCCC]

3,4-bis(2-(2-butoxyethoxy)ethoxy)thiophene [referred to herein as 3,4-diBEET].

It would be apparent to a person of ordinary skill in the art that the polythiophene polymer may be a copolymer comprising repeating units derived from both 3-substituted thiophene monomers and 3,4-disubstituted thiophene monomers.

3,4-disubstituted thiophene monomers, including polymers derived from such monomers, are commercially-available or may be made by methods known to those of ordinary skill in the art. For example, a 3,4-disubstituted thiophene monomer may be produced by reacting 3,4-dibromothiophene with the metal salt, typically sodium salt, of a compound given by the formula HO[C(RₐR_{b})—C(R_{c}R_{d})—O]ₚ—Rₑ or HOR_{f}, wherein Rₐ-R_{f} and p are as defined herein.

The polymerization of 3,4-disubstituted thiophene monomers may be carried out by, first, brominating the 2 and 5 positions of the 3,4-disubstituted thiophene monomer to form the corresponding 2,5-dibromo derivative of the 3,4-disubstituted thiophene monomer. The polymer can then be obtained by GRIM (Grignard methathesis) polymerization of the 2,5-dibromo derivative of the 3,4-disubstituted thiophene in the presence of a nickel catalyst. Such a method is described, for example, in U.S. Pat. No. 8,865,025, the entirety of which is hereby incorporated by reference. Another known method of polymerizing thiophene monomers is by oxidative polymerization using organic non-metal containing oxidants, such as 2,3-dichloro-5,6-dicyano-1,4-benzoquinone (DDQ), or using a transition metal halide, such as, for example, iron(III) chloride, molybdenum(V) chloride, and ruthenium(III) chloride, as oxidizing agent.

Examples of compounds having the formula HO[C(RₐR_{b})—C(R_{c}R_{d})—O]ₚ—Rₑ or HOR_{f} that may be converted to the metal salt, typically sodium salt, and used to produce 3,4-disubstituted thiophene monomers include, but are not limited to, trifluoroethanol, ethylene glycol monohexyl ether (hexyl Cellosolve), propylene glycol monobutyl ether (Dowanol PnB), diethylene glycol monoethyl ether (ethyl Carbitol), dipropylene glycol n-butyl ether (Dowanol DPnB), diethylene glycol monophenyl ether (phenyl Carbitol), ethylene glycol monobutyl ether (butyl Cellosolve), diethylene glycol monobutyl ether (butyl Carbitol), dipropylene glycol monomethyl ether (Dowanol DPM), diisobutyl carbinol, 2-ethylhexyl alcohol, methyl isobutyl carbinol, ethylene glycol monophenyl ether (Dowanol Eph), propylene glycol monopropyl ether (Dowanol PnP), propylene glycol monophenyl ether (Dowanol PPh), diethylene glycol monopropyl ether (propyl Carbitol), diethylene glycol monohexyl ether (hexyl Carbitol), 2-ethylhexyl carbitol, dipropylene glycol monopropyl ether (Dowanol DPnP), tripropylene glycol monomethyl ether (Dowanol TPM), diethylene glycol monomethyl ether (methyl Carbitol), and tripropylene glycol monobutyl ether (Dowanol TPnB).

The conjugated polymers, typically polythiophenes, according to the present disclosure may be further modified subsequent to their formation by polymerization. For instance, polythiophenes having one or more repeating units derived from 3-substituted thiophene monomers may possess one or more sites where hydrogen may be replaced by a substituent, such as a sulfonic acid group (—SO₃H) by sulfonation. Sulfonation may be achieved using methods known to those of ordinary skill in the art. For example, the sulfonation may be achieved by reacting the polymer with a sulfonating reagent such as, for example, fuming sulfuric acid, acetyl sulfate, pyridine SO₃, or the like. In an embodiment, however, the conjugated polymer, typically polythiophene, of the ink composition described herein is free of sulfonic acid groups.

The conjugated polymers used according to the present disclosure may be homopolymers, copolymers, including statistical, random, gradient, and block copolymers. For a polymer comprising a monomer A and a monomer B, block copolymers include, for example, A-B diblock copolymers, A-B-A triblock copolymers, and -(AB)ₙ-multiblock copolymers. The conjugated polymer may comprise repeating units derived from other types of monomers such as, for example, thienothiophenes, selenophenes, pyrroles, furans, tellurophenes, anilines, arylamines, and arylenes, such as, for example, phenylenes, phenylene vinylenes, and fluorenes.

In an embodiment, the polythiophene comprises repeating units complying with formula (I) in an amount of greater than 70% by weight, typically greater than 80% by weight, more typically greater than 90% by weight, even more typically greater than 95% by weight, based on the total weight of the repeating units.

It would be clear to a person of ordinary skill in the art that, depending on the purity of the starting monomer compound(s) used in the polymerization, the polymer formed may contain repeating units derived from impurities. As used herein, the term “homopolymer” is intended to mean a polymer comprising repeating units derived from one type of monomer, but may contain repeating units derived from impurities. In an embodiment, the polythiophene is a homopolymer wherein essentially all of the repeating units are repeating units complying with formula (I).

The conjugated polymer typically has a number average molecular weight between about 1,000 and 1,000,000 g/mol. More typically, the conjugated polymer has a number average molecular weight between about 5,000 and 100,000 g/mol, even more typically about 10,000 to about 50,000 g/mol. Number average molecular weight may be determined according to methods known to those of ordinary skill in the art, such as, for example, by gel permeation chromatography.

Additional hole carrier compounds are also described in, for example, US Patent Publications 2010/0292399 published Nov. 18, 2010; 2010/010900 published May 6, 2010; and 2010/0108954 published May 6, 2010.

The polymeric acid suitable for use according to the present disclosure is a polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group.

In an embodiment, the at least one polymeric acid comprises a repeating unit complying with formula (II) and a repeating unit complying with formula (III)

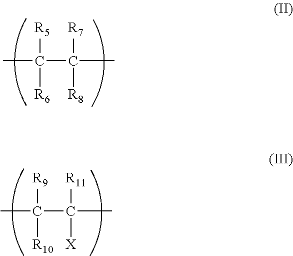

wherein each occurrence of R₅, R₆, R₇, R₈, R₉, R₁₀, and R₁₁ is, independently, H, halogen, fluoroalkyl, or perfluoroalkyl; and X is —[OC(RₕRᵢ)—C(RⱼRₖ)]_{q}—O—[CRₗRₘ]_{z}—SO₃H, wherein each occurrence of Rₕ, Rᵢ, Rⱼ, Rₖ, Rₗ and Rₘ is, independently, H, halogen, fluoroalkyl, or perfluoroalkyl; q is 0 to 10; and z is 1-5.

In an embodiment, each occurrence of R₅, R₆, R₇, and R₈ is, independently, Cl or F. In an embodiment, each occurrence of R₅, R₇, and R₈ is F, and R₆ is Cl. In an embodiment, each occurrence of R₅, R₆, R₇, and R₈ is F.

In an embodiment, each occurrence of R₉, R₁₀, and R₁₁ is F.

In an embodiment, each occurrence of Rₕ, Rᵢ, Rⱼ, Rₖ, Rₗ and Rₘ is, independently, F, (C₁-C₈)fluoroalkyl, or (C₁-C₈)perfluoroalkyl.

In an embodiment, each occurrence of Rₗ and Rₘ is F; q is 0; and z is 2.

In an embodiment, each occurrence of R₅, R₇, and R₈ is F, and R₆ is Cl; and each occurrence of Rₗ and Rₘ is F; q is 0; and z is 2.

In an embodiment, each occurrence of R₅, R₆, R₇, and R₈ is F; and each occurrence of Rₗ and Rₘ is F; q is 0; and z is 2.

The ratio of the number of repeating units complying with formula (II) (“n”) to the number of the repeating units complying with formula (III) (“m”) is not particularly limited. The n:m ratio is typically from 9:1 to 1:9, more typically 8:2 to 2:8. In an embodiment, the n:m ratio is 9:1. In an embodiment, the n:m ratio is 8:2.

The polymeric acid suitable for use according to the present disclosure may be synthesized using methods known to those of ordinary skill in the art or obtained from commercially-available sources. For instance, the polymers comprising a repeating unit complying with formula (II) and a repeating unit complying with formula (III) may be made by co-polymerizing monomers represented by formula (IIa) with monomers represented by formula (IIa)

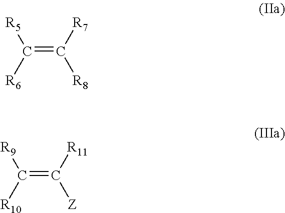

wherein Z is —[OC(RₕRᵢ)—C(RⱼRₖ)]_{q}—O—[CRₗRₘ]_{z}—SO₂F, wherein Rₕ, Rᵢ, Rⱼ, Rₖ, Rₗ and Rₘ, q, and z are as defined herein, according to known polymerization methods, followed by conversion to sulfonic acid groups by hydrolysis of the sulfonyl fluoride groups.

For example, tetrafluoroethylene (TFE) or chlorotrifluoroethylene (CTFE) may be copolymerized with one or more fluorinated monomers comprising a precursor group for sulfonic acid, such as, for example, F₂C═CF—O—CF₂—CF₂—SO₂F; F₂C═CF—[O—CF₂—CR₁₂F—O]_{q}—CF₂—CF₂—SO₂F, wherein R₁₂ is F or CF₃ and q is 1 to 10; F₂C═CF—O—CF₂—CF₂—CF₂—SO₂F; and F₂C═CF—OCF₂—CF₂—CF₂—CF₂—SO₂F.

The equivalent weight of the polymeric acid is defined as the mass, in grams, of the polymeric acid per mole of acidic groups present in the polymeric acid. The equivalent weight of the polymeric acid is from about 400 to about 15,000 g polymer/mol acid, typically from about 500 to about 10,000 g polymer/mol acid, more typically from about 500 to 8,000 g polymer/mol acid, even more typically from about 500 to 2,000 g polymer/mol acid, still more typically from about 600 to about 1,700 g polymer/mol acid.

Suitable polymeric acids are, for instance, those marketed by E. I. DuPont under the trade name NAFION®, those marketed by Solvay Specialty Polymers under the trade name AQUIVION®, or those marketed by Asahi Glass Co. under the trade name FLEMION®.

In the ink composition according to the present disclosure, the hole carrier compound-to-polymeric acid (hole carrier compound:polymeric acid ratio), by weight, is from 10:90 to 90:10, typically from 20:80 to 80:20, more typically from 35:65 to 65:35. In an embodiment, the hole carrier compound:polymeric acid ratio, by weight, is from 10:90 to 25:75. In another embodiment, the hole carrier compound:polymeric acid ratio, by weight, is from 35:65 to 40:60. In yet another embodiment, the hole carrier compound:polymeric acid ratio, by weight, is from 45:55 to 50:50.

In an embodiment, the ink composition according to the present disclosure further comprises one or more optional matrix compounds known to be useful in hole injection layers (HILs) or hole transport layers (HTLs).

The matrix compound can be a lower or higher molecular weight compound, and is different from the conjugated polymer and/or polymeric acid described herein. The matrix compound can be, for example, a synthetic polymer that is different from the conjugated polymer and/or polymeric acid. See, for example, US Patent Publication No. 2006/0175582 published Aug. 10, 2006. The synthetic polymer can comprise, for example, a carbon backbone. In some embodiments, the synthetic polymer has at least one polymer side group comprising an oxygen atom or a nitrogen atom. The synthetic polymer may be a Lewis base. Typically, the synthetic polymer comprises a carbon backbone and has a glass transition temperature of greater than 25° C. The synthetic polymer may also be a semi-crystalline or crystalline polymer that has a glass transition temperature equal to or lower than 25° C. and/or a melting point greater than 25° C. The synthetic polymer may comprise acidic groups.

The matrix compound can be a planarizing agent. A matrix compound or a planarizing agent may be comprised of, for example, a polymer or oligomer such as an organic polymer, such as poly(styrene) or poly(styrene) derivatives; poly(vinyl acetate) or derivatives thereof; poly(ethylene glycol) or derivatives thereof; poly(ethylene-co-vinyl acetate); poly(pyrrolidone) or derivatives thereof (e.g., poly(1-vinylpyrrolidone-co-vinyl acetate)); poly(vinyl pyridine) or derivatives thereof; poly(methyl methacrylate) or derivatives thereof; poly(butyl acrylate); poly(aryl ether ketones); poly(aryl sulfones); poly(esters) or derivatives thereof; or combinations thereof.

The matrix compound or a planarizing agent may be comprised of, for example, at least one semiconducting matrix component. The semiconducting matrix component is different from the conjugated polymer and/or polymeric acid described herein. The semiconducting matrix component can be a semiconducting small molecule or a semiconducting polymer that is typically comprised of repeat units comprising hole carrying units in the main-chain and/or in a side-chain. The semiconducting matrix component may be in the neutral form or may be doped, and is typically soluble and/or dispersible in organic solvents, such as toluene, chloroform, acetonitrile, cyclohexanone, anisole, chlorobenzene, o-dichlorobenzene, ethyl benzoate and mixtures thereof.

The amount of the optional matrix compound can be controlled and measured as a weight percentage relative to the amount of the hole carrier compound and polymeric acid combined. In an embodiment, the amount of the optional matrix compound is from 0 to 99.5 wt. %, typically from about 10 wt. to about 98 wt. %, more typically from about 20 wt. % to about 95 wt. %, still more typically about 25 wt. % to about 45 wt. %. In the embodiment with 0 wt. %, the ink composition is free of matrix compound.

The ink composition of the present disclosure is non-aqueous. As used herein, “non-aqueous” means that the total amount of protic solvent or solvents in the ink composition of the present disclosure is from 0 to 5% wt., with respect to the total amount of the liquid carrier. Typically, the total amount of protic solvent or solvents in the ink composition is from 0 to 2% wt, more typically from 0 to 1% wt, with respect to the total amount of the liquid carrier. As used herein, protic solvents are solvents having one or more functional groups in which a hydrogen atom is bonded to an oxygen atom and said oxygen atom is bonded to another hydrogen atom or a sp³-hybridized carbon atom. Protic solvents include, but are not limited to, water and alcohols, including polyols, such as diols and triols. Protic solvents are avoided in the ink compositions of the present disclosure because the presence of protic solvents in combination with the sulfonic acid groups of the polymeric acid leads to, for example, corrosiveness of the ink composition, deterioration of the films made from the ink compositions, and/or reduced lifetimes of the devices comprising such films. In an embodiment, the ink composition of the present disclosure is free of any protic solvent or solvents.

The liquid carrier used in the ink composition according to the present disclosure comprises at least one organic solvent. In an embodiment, the ink composition consists essentially of or consists of at least one organic solvent. The liquid carrier may be an organic solvent or solvent blend comprising two or more organic solvents adapted for use and processing with other layers in a device such as the anode or light emitting layer.

Organic solvents suitable for use in the liquid carrier include, but are not limited to, aliphatic and aromatic ketones, tetrahydrofuran (THF), tetrahydropyran (THP), chloroform, alkylated benzenes, halogenated benzenes, N-methylpyrrolidinone (NMP), dimethylformamide (DMF), dimethylacetamide (DMAc), dimethyl sulfoxide (DMSO), dichloromethane, acetonitrile, dioxanes, ethyl acetate, ethyl benzoate, methyl benzoate, dimethyl carbonate, ethylene carbonate, propylene carbonate, 3-methoxypropionitrile, 3-ethoxypropionitrile, or combinations thereof. The conjugated polymer and/or the polymeric acid is/are typically highly soluble and highly processable in these solvents.

Aliphatic and aromatic ketones include, but are not limited to, acetone, acetonyl acetone, methyl ethyl ketone (MEK), methyl isobutyl ketone, methyl isobutenyl ketone, 2-hexanone, 2-pentanone, acetophenone, ethyl phenyl ketone, cyclohexanone, and cyclopentanone. In some embodiments, ketones with protons on the carbon located alpha to the ketone are avoided, such as cyclohexanone, methyl ethyl ketone, and acetone.

Other organic solvents might also be considered that solubilize the conjugated polymer, that swell the conjugated polymer, or that even act as non-solvents for the conjugated polymer. Such other solvents may be included in the liquid carrier in varying quantities to modify ink properties such as wetting, viscosity, morphology control.

Other organic solvents suitable for use according to the present disclosure include ethers such as anisole, ethoxybenzene, dimethoxy benzenes and glycol ethers, such as, ethylene glycol diethers, such as 1,2-dimethoxyethane, 1,2-diethoxyethane, and 1,2-dibutoxyethane; diethylene glycol diethers such as diethylene glycol dimethyl ether, and diethylene glycol diethyl ether; propylene glycol diethers such as propylene glycol dimethyl ether, propylene glycol diethyl ether, and propylene glycol dibutyl ether; dipropylene glycol diethers, such as dipropylene glycol dimethyl ether, dipropylene glycol diethyl ether, and dipropylene glycol dibutyl ether; as well as higher analogues (i.e., tri- and tetra-analogues) of the ethylene glycol and propylene glycol ethers mentioned herein.

Still other solvents can be considered, such as ethylene glycol monoether acetates and propylene glycol monoether acetates, wherein the ether can be selected, for example, from methyl, ethyl, n-propyl, iso-propyl, n-butyl, sec-butyl, tert-butyl, and cyclohexyl. Also, higher glycol ether analogues of above list such as di-, tri- and tetra-. Examples include, but are not limited to, propylene glycol methyl ether acetate, 2-ethoxyethyl acetate, 2-butoxyethyl acetate.

As disclosed herein, the organic solvents disclosed herein can be used in varying proportions in the liquid carrier, for example, to improve the ink characteristics such as substrate wettability, ease of solvent removal, viscosity, surface tension, and jettability.

In some embodiments, the use of aprotic non-polar solvents can provide the additional benefit of increased life-times of devices with emitter technologies which are sensitive to protons, such as, for example, PHOLEDs.

The total solids content (% TS) in the ink composition according to the present disclosure is from about 0.1 wt. % to about 50 wt. %, typically from about 0.3 wt. % to about 40 wt. %, more typically from about 0.5 wt. % to about 10 wt. %, still more typically from about 0.6 wt. % to about 5 wt. %, with respect to the total amount of ink composition. In an embodiment, the total solids content in the ink composition is from about 5 wt. % to about 40 wt. %, with respect to the total amount of ink composition.

The amount of liquid carrier in the ink composition according to the present disclosure is from about 50 wt. % to about 99 wt. %, typically from about 75 wt. % to about 98 wt. %, still more typically from about 90 wt. % to about 95 wt. %, with respect to the total amount of ink composition.

The ink composition of the present disclosure may be prepared according to any method known to those of ordinary skill in the art. For example, the ink composition may be prepared by mixing an amount each of hole carrier compound, polymeric acid, and solvent or blend of solvents in a container. Alternatively, a solution of hole carrier compound in a first solvent or solvent blend and a solution of polymeric acid in a second solvent or solvent blend, which may be same or different from the first solvent or solvent blend, may be mixed to obtain the ink composition of the present disclosure.

The ink composition according to the present disclosure can be cast and annealed as a film on a substrate.

Thus, the present disclosure also relates to a process for forming a hole-carrying film, the process comprising:
1) coating a substrate with a non-aqueous ink composition disclosed herein; and
2) annealing the coating on the substrate, thereby forming the hole-carrying film.

The coating of the ink composition on a substrate can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

The substrate can be flexible or rigid, organic or inorganic. Suitable substrate compounds include, for example, glass, including, for example, display glass, ceramic, metal, and plastic films.

As used herein, the term “annealing” refers to the process of heating the coating layered on the substrate to a certain temperature (annealing temperature), maintaining the temperature for a certain period of time (annealing time), and then allowing the resulting layer, typically a film, to slowly cool to room temperature. The process of annealing may improve the mechanical and/or electrical properties of the polythiophene polymer and/or the polymeric acid by, for example, reducing or removing internal stresses and strains, reducing or removing defects, and aligning the polymer chains to improve structural ordering. It would be understood by the ordinarily-skilled artisan that the liquid carrier may be partially or completely evaporated during the course of the annealing process.

The step of annealing can be carried out by heating the substrate coated with the ink composition using any method known to those of ordinary skill in the art, for example, by heating in an oven or on a hot plate. Annealing can be carried out under an inert environment, for example, nitrogen atmosphere or noble gas atmosphere, such as, for example, argon gas. Annealing may be carried out in air atmosphere.

The annealing temperature used in the annealing step is a temperature effective for the polymeric acid described herein to dope the hole carrier compound. Dopants are generally known in the art. See, for example, U.S. Pat. No. 7,070,867; US Publication 2005/0123793; and US Publication 2004/0113127. However, the ink composition described herein is free of any dopant different from the polymeric acid described herein.

The temperature effective to dope the hole carrier compound may be determined by observing the UV-vis spectra of the wet film prior to annealing and the film subsequent to annealing. Before annealing, the hole carrier compound will exhibit characteristic absorbances. After annealing, the characteristic absorbances of the hole carrier compound will be attenuated or missing, indicating partial doping or complete doping, respectively. In an embodiment, the temperature effective to dope the hole carrier compound temperature is from about 25° C. to about 300° C., typically 150° C. to about 250° C.

The annealing time is the time for which the annealing temperature is maintained. The annealing time is from about 5 to about 40 minutes, typically from about 15 to about 30 minutes.

In an embodiment, the annealing temperature is from about 25° C. to about 300° C., typically 150° C. to about 250° C., and the annealing time is from about 5 to about 40 minutes, typically for about 15 to about 30 minutes.

The present disclosure relates to the hole-carrying film formed by the process described herein.

Transmission of visible light is important, and good transmission (low absorption) at higher film thicknesses is particularly important. For example, the film made according to the process of the present disclosure can exhibit a transmittance (typically, with a substrate) of at least about 85%, typically at least about 90%, of light having a wavelength of about 380-800 nm. In an embodiment, the transmittance is at least about 90%.

In one embodiment, the film made according to the process of the present disclosure has a thickness of from about 5 nm to about 500 nm, typically from about 5 nm to about 150 nm, more typically from about 50 nm to 120 nm.

In an embodiment, the film made according to the process of the present disclosure exhibits a transmittance of at least about 90% and has a thickness of from about 5 nm to about 500 nm, typically from about 5 nm to about 150 nm, more typically from about 50 nm to 120 nm. In an embodiment, the film made according to the process of the present disclosure exhibits a transmittance (% T) of at least about 90% and has a thickness of from about 50 nm to 120 nm.

The films made according to the processes of the present disclosure may be made on a substrate optionally containing an electrode or additional layers used to improve electronic properties of a final device. The resulting films may be intractable to one or more organic solvents, which can be the solvent or solvents used as liquid carrier in the ink for subsequently coated or deposited layers during fabrication of a device. The films may be intractable to, for example, toluene, which can be the solvent in the ink for subsequently coated or deposited layers during fabrication of a device.

The present disclosure also relates to a device comprising a film prepared according to the processes described herein. The devices described herein can be made by methods known in the art including, for example, solution processing. Inks can be applied and solvents removed by standard methods. The film prepared according to the processes described herein may be an HIL and/or HTL layer in the device.

Methods are known in the art and can be used to fabricate organic electronic devices including, for example, OLED and OPV devices. Methods known in the art can be used to measure brightness, efficiency, and lifetimes. Organic light emitting diodes (OLED) are described, for example, in U.S. Pat. Nos. 4,356,429 and 4,539,507 (Kodak). Conducting polymers which emit light are described, for example, in U.S. Pat. Nos. 5,247,190 and 5,401,827 (Cambridge Display Technologies). Device architecture, physical principles, solution processing, multilayering, blends, and compounds synthesis and formulation are described in Kraft et al., “Electroluminescent Conjugated Polymers-Seeing Polymers in a New Light,” Angew. Chem. Int. Ed., 1998, 37, 402-428, which is hereby incorporated by reference in its entirety.

Light emitters known in the art and commercially available can be used including various conducting polymers as well as organic molecules, such as compounds available from Sumation, Merck Yellow, Merck Blue, American Dye Sources (ADS), Kodak (e.g., A1Q3 and the like), and even Aldrich, such as BEHP-PPV. Examples of such organic electroluminescent compounds include:

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(p-phenylene vinylene) and its derivatives substituted at various positions on the phenylene moiety and also substituted at various positions on the vinylene moiety;

(iv) poly(arylene vinylene), where the arylene may be such moieties as naphthalene, anthracene, furylene, thienylene, oxadiazole, and the like;

(v) derivatives of poly(arylene vinylene), where the arylene may be as in (iv) above, and additionally have substituents at various positions on the arylene; (vi) derivatives of poly(arylene vinylene), where the arylene may be as in (iv) above, and additionally have substituents at various positions on the vinylene; (vii) derivatives of poly(arylene vinylene), where the arylene may be as in (iv) above, and additionally have substituents at various positions on the arylene and substituents at various positions on the vinylene;

(viii) co-polymers of arylene vinylene oligomers, such as those in (iv), (v), (vi), and (vii) with non-conjugated oligomers; and

(ix) poly(p-phenylene) and its derivatives substituted at various positions on the phenylene moiety, including ladder polymer derivatives such as poly(9,9-dialkyl fluorene) and the like;

(x) poly(arylenes) where the arylene may be such moieties as naphthalene, anthracene, furylene, thienylene, oxadiazole, and the like; and their derivatives substituted at various positions on the arylene moiety;

(xi) co-polymers of oligoarylenes, such as those in (x) with non-conjugated oligomers;

(xii) polyquinoline and its derivatives;

(xiii) co-polymers of polyquinoline with p-phenylene substituted on the phenylene with, for example, alkyl or alkoxy groups to provide solubility; and

(xiv) rigid rod polymers, such as poly(p-phenylene-2,6-benzobisthiazole), poly(p-phenylene-2,6-benzobisoxazole), poly(p-phenylene-2,6-benzimidazole), and their derivatives;

(xv) polyfluorene polymers and co-polymers with polyfluorene units.

Preferred organic emissive polymers include SUMATION Light Emitting Polymers (“LEPs”) that emit green, red, blue, or white light or their families, copolymers, derivatives, or mixtures thereof; the SUMATION LEPs are available from Sumation KK. Other polymers include polyspirofluorene-like polymers available from Covion Organic Semiconductors GmbH, Frankfurt, Germany (now owned by Merck®).

Alternatively, rather than polymers, small organic molecules that emit by fluorescence or by phosphorescence can serve as the organic electroluminescent layer. Examples of small-molecule organic electroluminescent compounds include: (i) tris(8-hydroxyquinolinato) aluminum (Alq); (ii) 1,3-bis(N,N-dimethylaminophenyl)-1,3,4-oxidazole (OXD-8); (iii) -oxo-bis(2-methyl-8-quinolinato)aluminum; (iv) bis(2-methyl-8-hydroxyquinolinato) aluminum; (v) bis(hydroxybenzoquinolinato) beryllium (BeQ₂); (vi) bis(diphenylvinyl)biphenylene (DPVBI); and (vii) arylamine-substituted distyrylarylene (DSA amine).

Such polymer and small-molecule compounds are well known in the art and are described in, for example, U.S. Pat. No. 5,047,687.

The devices can be fabricated in many cases using multilayered structures which can be prepared by, for example, solution or vacuum processing, as well as printing and patterning processes. In particular, use of the embodiments described herein for hole injection layers (HILs), wherein the composition is formulated for use as a hole injection layer, can be carried out effectively.

Examples of HIL in devices include:

1) Hole injection in OLEDs including PLEDs and SMOLEDs; for example, for HIL in PLED, all classes of conjugated polymeric emitters where the conjugation involves carbon or silicon atoms can be used. For HIL in SMOLED, the following are examples: SMOLED containing fluorescent emitters; SMOLED containing phosphorescent emitters; SMOLEDs comprising one or more organic layers in addition to the HIL layer; and SMOLEDs where the small molecule layer is processed from solution or aerosol spray or any other processing methodology. In addition, other examples include HIL in dendrimer or oligomeric organic semiconductor based OLEDs; HIL in ambipolar light emitting FET's where the HIL is used to modify charge injection or as an electrode;

2) Hole extraction layer in OPV;

3) Channel material in transistors;

4) Channel material in circuits comprising a combination of transistors, such as logic gates;

5) Electrode material in transistors;

6) Gate layer in a capacitor;

7) Chemical sensor where modification of doping level is achieved due to association of the species to be sensed with the conductive polymer;

8) Electrode or electrolyte material in batteries.

A variety of photoactive layers can be used in OPV devices. Photovoltaic devices can be prepared with photoactive layers comprising fullerene derivatives mixed with, for example, conducting polymers as described in, for example, U.S. Pat. Nos. 5,454,880; 6,812,399; and 6,933,436. Photoactive layers may comprise blends of conducting polymers, blends of conducting polymers and semiconducting nanoparticles, and bilayers of small molecules such as phthalocyanines, fullerenes, and porphyrins.

Common electrode compounds and substrates, as well as encapsulating compounds can be used.

In one embodiment, the cathode comprises Au, Ca, Al, Ag, or combinations thereof. In one embodiment, the anode comprises indium tin oxide. In one embodiment, the light emission layer comprises at least one organic compound.

Interfacial modification layers, such as, for example, interlayers, and optical spacer layers may be used.

Electron transport layers can be used.

The present disclosure also relates to a method of making a device described herein.

In an embodiment, the method of making a device comprises: providing a substrate; layering a transparent conductor, such as, for example, indium tin oxide, on the substrate; providing the ink composition described herein; layering the ink composition on the transparent conductor to form a hole injection layer or hole transport layer; layering an active layer on the hole injection layer or hole transport layer (HTL); and layering a cathode on the active layer.

As described herein, the substrate can be flexible or rigid, organic or inorganic. Suitable substrate compounds include, for example, glass, ceramic, metal, and plastic films.

In another embodiment, a method of making a device comprises applying the ink composition as described herein as part of an HIL or HTL layer in an OLED, a photovoltaic device, an ESD, a SMOLED, a PLED, a sensor, a supercapacitor, a cation transducer, a drug release device, an electrochromic device, a transistor, a field effect transistor, an electrode modifier, an electrode modifier for an organic field transistor, an actuator, or a transparent electrode.

The layering of the ink composition to form the HIL or HTL layer can be carried out by methods known in the art including, for example, spin casting, spin coating, dip casting, dip coating, slot-dye coating, ink jet printing, gravure coating, doctor blading, and any other methods known in the art for fabrication of, for example, organic electronic devices.

In one embodiment, the HIL layer is thermally annealed. In one embodiment, the HIL layer is thermally annealed at temperature of about 25° C. to about 300° C., typically 150° C. to about 250° C. In one embodiment, the HIL layer is thermally annealed at temperature of about 25° C. to about 300° C., typically 150° C. to about 250° C., for about 5 to about 40 minutes, typically for about 15 to about 30 minutes.

In accordance with the present disclosure, an HIL or HTL can be prepared that can exhibit a transmittance (typically, with a substrate) of at least about 85%, typically at least about 90%, of light having a wavelength of about 380-800 nm. In an embodiment, the transmittance is at least about 90%.

In one embodiment, the HIL layer has a thickness of from about 5 nm to about 500 nm, typically from about 5 nm to about 150 nm, more typically from about 50 nm to 120 nm.

In an embodiment, the HIL layer exhibits a transmittance of at least about 90% and has a thickness of from about 5 nm to about 500 nm, typically from about 5 nm to about 150 nm, more typically from about 50 nm to 120 nm. In an embodiment, the HIL layer exhibits a transmittance (% T) of at least about 90% and has a thickness of from about 50 nm to 120 nm.

The inks, methods and processes, films, and devices according to the present disclosure are further illustrated by the following non-limiting examples.

### Example 1. Preparation of Non-Aqueous (NQ) Ink Compositions

The components used in the following examples are summarized in the Table 1.

TABLE 1
Summary of components

| | |
|---|---|
| Polymer A | poly(3,4-diBEET) |
| Polymer B | poly(3-MEET) |
| CTFE-VEFS | CTFE-VEFS copolymer having equivalent weight of 1624 g |
| | polymer/mol acid (available from Solvay as |
| | AQUIVION ® CTFE-VEFS); n:m = 9:1 |

The non-aqueous ink compositions according to the present disclosure were prepared by mixing the specified amount of polythiophene, polymeric acid, and solvent in a vial under inert atmosphere, followed by agitation in a shaker at 70° C. for >1 hour. The non-aqueous ink compositions are summarized in Table 2. The “wt %” used in Table 2 refers to the percent by weight of the conjugated polymer with respect to the combined weight of the conjugated polymer and the polymeric acid. As used in Table 2, AP21 refers to anisole/3-methoxypropionitrile blend (2:1 by weight) and NMP refers to N-methylpyrrolidinone. AP21/NMP refers to a 1:1 solvent blend.

TABLE 2
NQ ink compositions

| | | Amount of | | |
|---|---|---|---|---|
| | | polythiophene | Polymeric | |
| Ink | Polythiophene | (wt %) | acid | Solvent |
| 1 | Polymer A | 10 | CTFE-VEFS | NMP |
| 2 | Polymer A | 25 | CTFE-VEFS | NMP |
| 3 | Polymer B | 10 | CTFE-VEFS | NMP |
| 4 | Polymer B | 25 | CTFE-VEFS | NMP |
| 5 | Polymer A | 10 | CTFE-VEFS | AP21/NMP |
| 6 | Polymer A | 25 | CTFE-VEFS | AP21/NMP |

### Example 2. Film Formation and Characterization

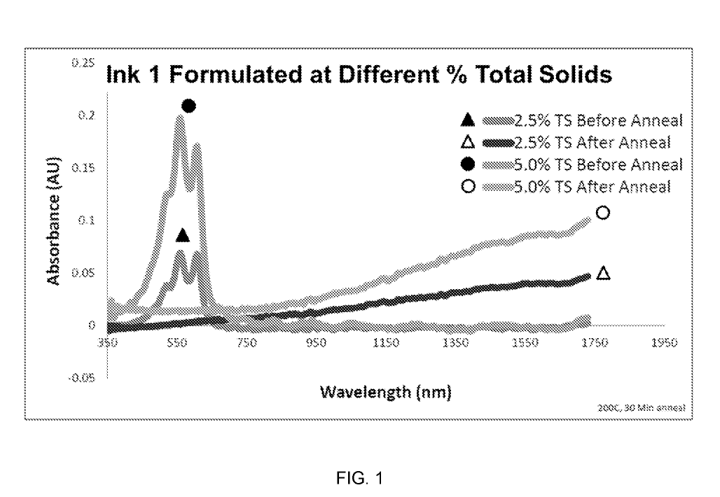

Ink 1 of Example 1 was formulated at 2.5% total solids content (TS), herein designated Ink 1a, and at 5.0% TS, herein designated Ink 1b. Each of Inks 1a and 1b were filtered through a 0.45 μm syringe filter and then spin-coated on a substrate at 1,000 RPM for 90 seconds under inert atmosphere, unless otherwise stated. The UV-vis spectra of the wet films were obtained. The wet films were then annealed at 200° C. under inert atmosphere, after which the UV-vis spectra of the annealed films were again obtained. The UV-vis spectral results are shown in FIG. 1.

As shown in FIG. 1, the wet films prepared from Inks 1a and 1b both show absorbances (around 550 nm) characteristic of undoped Polymer A. However, following annealing at 200° C. under inert atmosphere, the absorbance that was characteristic of undoped Polymer A was not detected, indicating that Polymer A is doped.

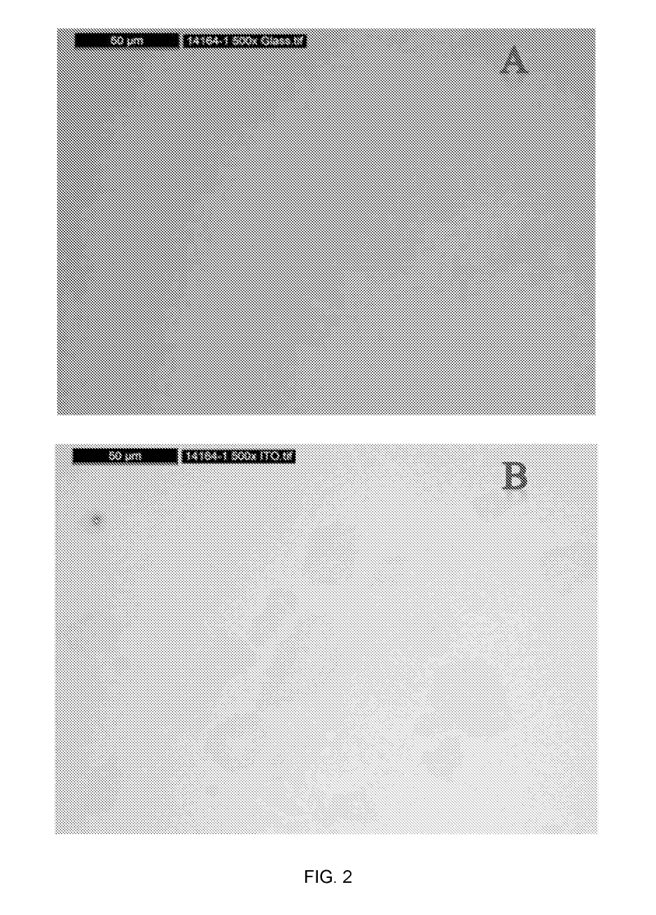

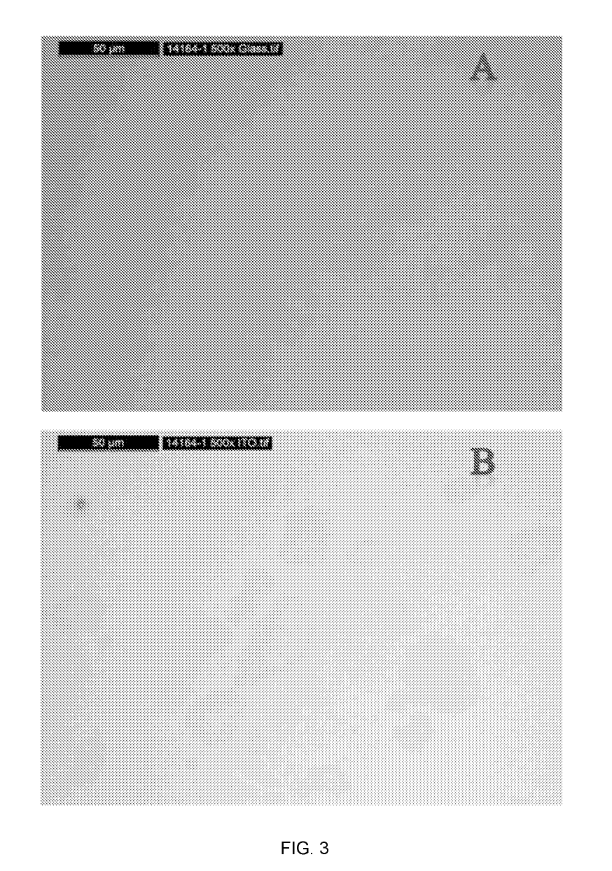

Further analysis of the annealed films formed from the inventive inks revealed a resistivity of 500 Ω·cm and a work function of −5.31 eV. The films formed from the inventive inks were also examined by optical microscopy under 500× and 1000× magnification. FIGS. 2A and 2B shows the images of films formed on glass and films formed on ITO, respectively, under 500× magnification. FIGS. 3A and 3B shows the images of films formed on glass and films formed on ITO, respectively, under 1000× magnification.

### Example 3. Unipolar Device Fabrication and Testing

The unipolar, single charge-carrier devices described herein were fabricated on indium tin oxide (ITO) surfaces deposited on glass substrates. The ITO surface was pre-patterned to define the pixel area of 0.05 cm². Before depositing an HIL ink composition on the substrates, pre-conditioning of the substrates was performed. The device substrates were first cleaned by ultrasonication in various solutions or solvents. The device substrates were ultrasonicated in a dilute soap solution, followed by distilled water, then acetone, and then isopropanol, each for about 20 minutes. The substrates were dried under nitrogen flow. Subsequently, the device substrates were then transferred to a vacuum oven set at 120° C. and kept under partial vacuum (with nitrogen purging) until ready for use. The device substrates were treated in a UV-Ozone chamber operating at 300 W for 20 minutes immediately prior to use.

Before the HIL ink composition is deposited onto an ITO surface, filtering of the ink composition through a PTFE 0.45-μm filter is performed.

The HIL was formed on the device substrate by spin coating. Generally, the thickness of the HIL after spin-coating onto the ITO-patterned substrates is determined by several parameters such as spin speed, spin time, substrate size, quality of the substrate surface, and the design of the spin-coater. General rules for obtaining certain layer thickness are known to those of ordinary skill in the art. After spin-coating, the HIL layer was dried on a hot plate, typically at a temperature (anneal temperature) of from 150° C. to 250° C. for 15-30 minutes.

The substrates comprising the inventive HIL layers were then transferred to a vacuum chamber where the remaining layers of the device stack were deposited by means of physical vapor deposition.

All steps in the coating and drying process are done under an inert atmosphere, unless otherwise stated.

N,N′-bis(1-naphtalenyl)-N,N′-bis(phenyl)benzidine (NPB) was deposited as a hole transport layer on top of the HIL followed by a gold (Au) or aluminum (Al) cathode. The typical device stack, including target film thickness, for the unipolar device, is ITO (220 nm)/HIL (100 nm)/NPB (150 nm)/Al (100 nm). This is a unipolar device wherein the hole-only injection efficiency of the HIL into the HTL is studied.

The unipolar device comprises pixels on a glass substrate whose electrodes extended outside the encapsulated area of the device which contain the light emitting portion of the pixels. The typical area of each pixel is 0.05 cm². The electrodes were contacted with a current source meter such as a Keithley 2400 source meter with a bias applied to the ITO electrode while the gold or aluminum electrode was earthed. This results in only positively charged carriers (holes) being injected into the device (hole-only device).

Hole-only devices were fabricated using the inks and anneal temperature summarized in Table 3.

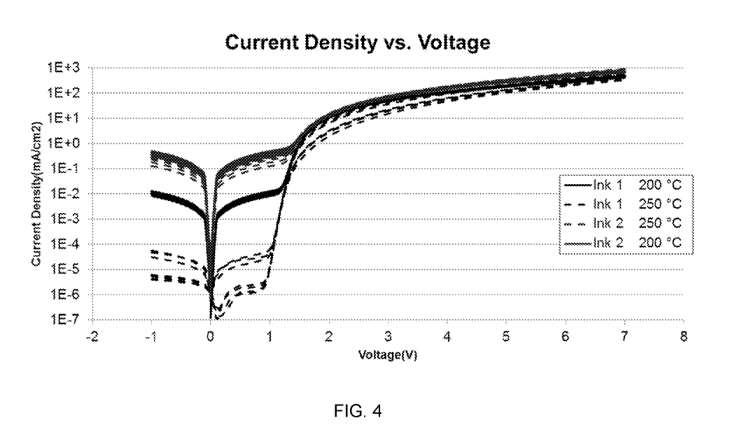

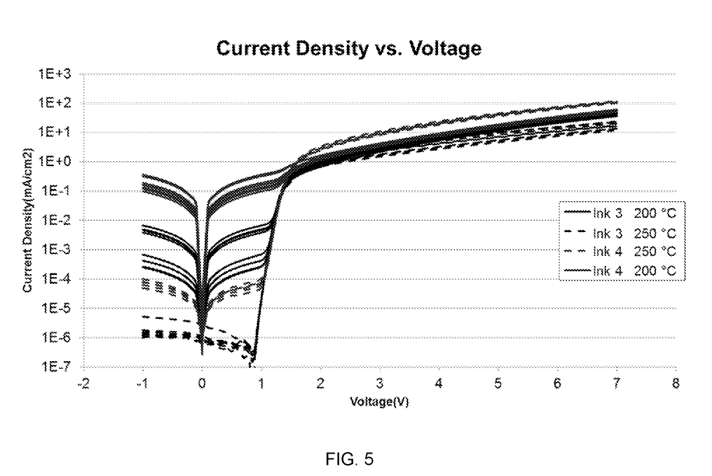

TABLE 3
Inventive HILs

| Ex. | Ink | Anneal temperature (° C.) | Current density vs. voltage |
|---|---|---|---|
| 3.1 | 1 | 200 | FIG. 4 |
| 3.2 | 1 | 250 | |
| 3.3 | 2 | 200 | |
| 3.4 | 2 | 250 | |
| 3.5 | 3 | 200 | FIG. 5 |
| 3.6 | 3 | 250 | |
| 3.7 | 4 | 200 | |
| 3.8 | 4 | 250 | |

The plots of current density as a function of voltage of the hole-only devices comprising HILs made from the inventive inks of the present disclosure are shown in FIG. 4 and FIG. 5.

What is claimed is:

1. A non-aqueous ink composition comprising:
(a) at least one hole carrier compound; and
(b) at least one polymeric acid comprising one or more repeating units comprising at least one alkyl or alkoxy group which is substituted by at least one fluorine atom and at least one sulfonic acid (—SO₃H) moiety, wherein said alkyl or alkoxy group is optionally interrupted by at least one ether linkage (—O—) group; and
(c) a liquid carrier comprising at least one organic solvent.

2. The non-aqueous ink composition according to claim 1, wherein the hole carrier compound is a conjugated polymer.

3. The non-aqueous ink composition according to claim 2, wherein the conjugated polymer is a polythiophene.

4. The non-aqueous ink composition according to claim 3, wherein the polythiophene comprises a repeating unit complying with formula (I) 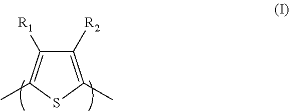
wherein R₁ and R₂ are each, independently, H, alkyl, fluoroalkyl, polyether, or alkoxy group.

5. The non-aqueous ink composition according to claim 4, wherein R₁ and R₂ are each, independently, H, fluoroalkyl, —O[C(RₐR_{b})—C(R_{c}R_{d})—O]ₚ—Rₑ, —OR_{f}; wherein each occurrence of Rₐ, R_{b}, R_{c}, and R_{d}, are each, independently, H, alkyl, fluoroalkyl, or aryl; Rₑ is H, alkyl, fluoroalkyl, or aryl; p is 1, 2, or 3; and R_{f} is alkyl, fluoroalkyl, or aryl.

6. The non-aqueous ink composition according to claim 5, wherein R₁ is H and R₂ is other than H.

7. The non-aqueous ink composition according to claim 6, wherein R₁ is H and R₂ is —O[C(RₐR_{b})—C(R_{c}R_{d})—O]ₚ—Rₑ, or —OR_{f}.

8. The non-aqueous ink composition according to claim 7, wherein R₁ is H and R₂ is —O[C(RₐR_{b})—C(R_{c}R_{d})—O]ₚ—Rₑ.

9. The non-aqueous ink composition according to claim 8, wherein the polythiophene comprises a repeating unit

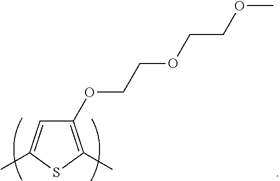

10. The non-aqueous ink composition according to claim 5, wherein R₁ and R₂ are both other than H.

11. The non-aqueous ink composition according to claim 10, wherein R₁ and R₂ are each, independently, —O[C(RₐR_{b})—C(R_{c}R_{d})—O]ₚ—Rₑ or —OR_{f}.

12. The non-aqueous ink composition according to claim 11, wherein R₁ and R₂ are both —O[C(RₐR_{b})—C(R_{c}R_{d})—O]ₚ—Rₑ.

13. The non-aqueous ink composition according to claim 12, wherein the polythiophene comprises a repeating unit

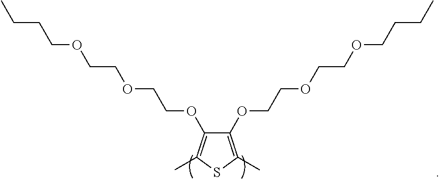

14. The non-aqueous ink composition according to any one of claims 4 to 13, wherein the polythiophene comprises repeating units complying with formula (I) in an amount of greater than 70% by weight, typically greater than 80% by weight, more typically greater than 90% by weight, even more typically greater than 95% by weight, based on the total weight of the repeating units.

15. The non-aqueous ink composition according to any one of claims 1 to 14, wherein the at least one polymeric acid comprises a repeating unit complying with formula (II) and a repeating unit complying with formula (III) 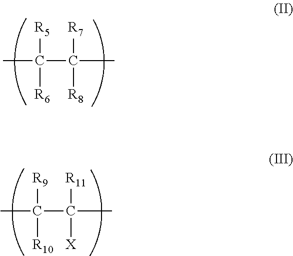
wherein
each occurrence of R₅, R₆, R₇, R₈, R₉, R₁₀, and R₁₁ is, independently, H, halogen, fluoroalkyl, or perfluoroalkyl; and
X is —[OC(RₕRᵢ)—C(RⱼRₖ)]_{q}—O—[CRₗRₘ]_{z}—SO₃H,
wherein each occurrence of Rₕ, Rᵢ, Rⱼ, Rₖ, Rₗ and Rₘ is, independently, H, halogen, fluoroalkyl, or perfluoroalkyl;
q is 0 to 10; and
z is 1-5.

16. The non-aqueous ink composition according to claim 15, wherein each occurrence of R₅, R₆, R₇, and R₈ is, independently, Cl or F.

17. The non-aqueous ink composition according to claim 16, wherein each occurrence of R₅, R₇, and R₈ is F, and R₆ is CI.

18. The non-aqueous ink composition according to claim 16, wherein each occurrence of R₅, R₆, R₇, and R₈ is F.

19. The non-aqueous ink composition according to any one of claims 15 to 18, wherein each occurrence of R₉, R₁₀, and R₁₁ is F.

20. The non-aqueous ink composition according to any one of claims 15 to 19, wherein each occurrence of Rₕ, Rᵢ, Rⱼ, Rₖ, Rₗ and Rₘ is, independently, F, (C₁-C₈)fluoroalkyl, or (C₁-C₈)perfluoroalkyl.

21. The non-aqueous ink composition according to any one of claims 15 to 20, wherein each occurrence of Rₗ and Rₘ is F; q is 0; and z is 2.

22. The non-aqueous ink composition according to any one of claims 15 to 21, wherein each occurrence of R₅, R₇, and R₈ is F, and R₆ is Cl; and each occurrence of Rₗ and Rₘ is F; q is 0; and z is 2.

23. The non-aqueous ink composition according to any one of claims 15 to 21, wherein each occurrence of R₅, R₆, R₇, and R₈ is F; and each occurrence of R₁ and Rₘ is F; q is 0; and z is 2.

24. The non-aqueous ink composition according to any one of claims 15 to 23, wherein the n:m ratio is 9:1.

25. The non-aqueous ink composition according to any one of claims 15 to 23, wherein the n:m ratio is 8:2.

26. The non-aqueous ink composition according to any one of claims 1 to 25, wherein the hole carrier compound: polymeric acid ratio, by weight, is from 10:90 to 90:10, typically from 20:80 to 80:20, more typically from 35:65 to 65:35.

27. The non-aqueous ink composition according to any one of claims 1 to 26, further comprising one or more matrix compounds.

28. A process for forming a hole-carrying film, the process comprising:
1) coating a substrate with a non-aqueous ink composition according to any one of claims 1 to 27; and
2) annealing the coating on the substrate, thereby forming the hole-carrying film.

29. The process according to claim 28, wherein the annealing temperature is a temperature effective for the polymeric acid to dope the hole carrier compound.

30. The process according to claim 29, wherein the temperature effective to dope the hole carrier compound temperature is from about 25° C. to about 300° C., typically 150° C. to about 250° C.

31. The process according to any one of claims 28 to 30, wherein the annealing time is from about 5 to about 40 minutes, typically from about 15 to about 30 minutes.

32. The hole-carrying film formed by the process according to any one of claims 28 to 31.

33. A device comprising the film according to claim 32, wherein the device is an OLED, OPV, transistor, capacitor, sensor, transducer, drug release device, electrochromic device, or battery device.
